(19) United States
(12) Patent Application Publication
(10) Pub. No.: US 2002/0140099 A1
(43) Pub. Date: Oct. 3, 2002

(54) Semiconductor device and method for manufacturing the same

(75) Inventors: Kaori Tsutsumi, Yokohama-shi (JP); Jota Fukuhara, Yokkaichi-shi (JP); Hirokazu Ezawa, Tokyo (JP)

Correspondence Address: Finnegan, Henderson, Farabow,, Garrett & Dunner, L.L.P., 1300 I Street, N.W., Washington, DC, 20005-3315, US

(73) Assignee: Kabushiki Kaisha Toshiba

(21) Appl. No.: 10/107,348

(22) Filed: Mar. 28, 2002

(30) Foreign Application Priority Data
Mar. 28, 2001 (JP) 2001-093660

(51) Int. Cl. H01L 23/48

(52) U.S. Cl. 257/758

(57) ABSTRACT

There is provided a semiconductor device comprising a semiconductor substrate, a first wiring formed above the semiconductor substrate and including a first polysilicon film containing a first conductivity type impurity and a first silicide film formed on the first polysilicon film and containing at least one of Co, Ni and Pd, a second wiring formed above the semiconductor substrate and including a second polysilicon film containing a second conductivity type impurity and connected to the first polysilicon film and a second silicide film formed on the second polysilicon film and containing at least one of Co, Ni and Pd, and a conductive connection member having a portion corresponding to a boundary region of the first polysilicon film and the second polysilicon film and connected to the first silicide film and the second silicide film.

### CROSS-REFERENCE TO RELATED APPLICATIONS

This application is based upon and claims the benefit of priority from the prior Japanese Patent Application No. 2001-093660, filed Mar. 28, 2001, the entire contents of which are incorporated herein by reference.

### BACKGROUND OF THE INVENTION

1. Field of the Invention

This invention relates to a semiconductor device having a wiring of laminate structure composed of a polysilicon film and a silicide film, and to the method of manufacturing such a semiconductor device.

2. Description of the Related Art

Due to a recent trend to further increase the fineness in structure of semiconductor device, it is increasingly demanded to lower the resistance of a gate electrode of an MIS transistor and of a wiring formed contiguous to the gate electrode (these gate electrode and wiring are herein referred to generically as a gate wiring). As for the means to lower the resistance of the gate wiring, there is known a laminate structure composed of a polysilicon film and a metal silicide film.

Such a gate wiring structure as mentioned above is disclosed for instance in U.S. Pat. No. 5,498,908; and Jpn. Pat. Appln. KOKAI Publications Nos. 3-203366 and 6-104259. These publications are aimed at preventing the mutual diffusion of P-type impurities and N-type impurities in the vicinity of the boundary between a P-type polysilicon film and an N-type polysilicon film. For this purpose, it is designed in these publications such that a portion of metal silicide film (such as a Ti silicide film, a W silicide film, etc.) which is formed on a boundary region of a P-type polysilicon film and an N-type polysilicon film is removed, and the resultant parted metal silicide films are connected with each other using a metal film.

However, according to the prior art mentioned above, a step of patterning is required for removing the metal silicide film. Therefore, at least a predetermined width of space based on a design rule, etc. is inevitably caused to be formed between the parted metal silicide films. Accordingly, the width of the pattern for connecting the parted metal silicide films is required to be larger than the aforementioned width of space, thus resulting in an increase of the area. Additional steps are also required for performing the patterning. Moreover, since a metal silicide such as a Ti silicide is relatively high in electric resistance, it is difficult to sufficiently lower the electric resistance of the gate wiring.

It is also proposed to employ Co silicide (CoSi₂) as a material which is lower in electric resistance than Ti silicide. However, when Co silicide is employed in place of Ti silicide, it would give rise to the problem that the yield is greatly deteriorated, thus making it difficult to apply Co silicide to the manufacture of a semiconductor device.

As explained above, when it is desired to employ a laminate structure composed of a polysilicon film and a metal silicide film for the formation of gate wiring, it is difficult to obtain a semiconductor device exhibiting a satisfactory performance.

### BRIEF SUMMARY OF THE INVENTION

According to a first aspect of the present invention, there is provided a semiconductor device comprising: a semiconductor substrate; a first wiring formed above the semiconductor substrate and including a first polysilicon film containing a first conductivity type impurity and a first silicide film formed on the first polysilicon film and containing at least one of Co, Ni and Pd; a second wiring formed above the semiconductor substrate and including a second polysilicon film containing a second conductivity type impurity and connected to the first polysilicon film and a second silicide film formed on the second polysilicon film and containing at least one of Co, Ni and Pd; and a conductive connection member having a portion corresponding to a boundary region of the first polysilicon film and the second polysilicon film and connected to the first silicide film and the second silicide film.

According to a second aspect of the present invention, there is provided a method of manufacturing a semiconductor device comprising: forming a polysilicon film above a semiconductor substrate; introducing a first conductivity type impurity into a first region of the polysilicon film and introducing a second conductivity type impurity into a second region of the polysilicon film; forming a metal film containing at least one of Co, Ni and Pd on the polysilicon film including the first and second regions; causing the metal film to react with the polysilicon film to form a first silicide film in the first region and a second silicide film in the second region; and forming a conductive connection member on a boundary region of the first region and the second region to connect the conductive connection member to the first silicide film and the second silicide film.

### BRIEF DESCRIPTION OF THE SEVERAL VIEWS OF THE DRAWING

FIG. 1 is a plan view illustrating a part of the structure of a semiconductor device according to one embodiment of the present invention;

FIGS. 2A, 2B and 2C represent a cross-sectional view taken along the line A-A′ of FIG. 1, a cross-sectional view taken along the line B-B′ of FIG. 1, and a cross-sectional view taken along the line C-C′ of FIG. 1, respectively;

FIGS. 3A and 3B are cross-sectional views each illustrating the structure of semiconductor device according to one embodiment of the present invention;

FIG. 4 is a plan view for illustrating the structure of semiconductor device according to one embodiment of the present invention;

FIGS. 5A, 5B and 5C are cross-sectional views each illustrating part of the manufacturing process of a semiconductor device according to one embodiment of the present invention;

FIGS. 6A, 6B and 6C are cross-sectional views each illustrating part of the manufacturing process of a semiconductor device according to one embodiment of the present invention;

FIGS. 7A, 7B and 7C are cross-sectional views each illustrating part of the manufacturing process of a semiconductor device according to one embodiment of the present invention;

FIGS. 8A, 8B and 8C are cross-sectional views each illustrating part of the manufacturing process of a semiconductor device according to one embodiment of the present invention;

FIGS. 9A, 9B and 9C are cross-sectional views each illustrating part of the manufacturing process of a semiconductor device according to one embodiment of the present invention;

FIGS. 10A, 10B and 10C are cross-sectional views each illustrating part of the manufacturing process of a semiconductor device according to one embodiment of the present invention;

FIGS. 11A, 11B and 11C are cross-sectional views each illustrating part of the manufacturing process of a semiconductor device according to one embodiment of the present invention;

FIGS. 12A, 12B and 12C are cross-sectional views each illustrating part of the manufacturing process of a semiconductor device according to one embodiment of the present invention;

FIGS. 13A, 13B and 13C are cross-sectional views each illustrating part of the manufacturing process of a semiconductor device according to one embodiment of the present invention; and

FIGS. 14A, 14B and 14C are cross-sectional views each illustrating the structure of semiconductor device according to another embodiment of the present invention.

### DETAILED DESCRIPTION OF THE INVENTION

Next, embodiments of the present invention will be explained with reference to drawings.

As already explained above, when a wiring is formed by making use of a laminate structure composed of a polysilicon film and a cobalt silicide film (CoSi₂ film), the yield is deteriorated. With a view to investigate the cause for this problem, the gate wiring where the aforementioned laminate structure was employed was analyzed. As a result, the Co silicide film was found as having regions where the Co silicide film was thinned or absent, resulting in the generation of abnormality in electric resistance of the wiring.

When the Co silicide film was investigated as to if there was any defectiveness in the formation thereof, the generation of defectiveness was found concentrated in the vicinity of the boundary between a polysilicon region where As ions or P ions were implanted (N⁺ region) and a polysilicon region where B ions were implanted (P⁺ region). As a result of an additional investigation, the generation of thick native oxide film was recognized in the vicinity of the boundary, suggesting that the formation of Co silicide was obstructed by this thick native oxide film.

When a Ti silicide (TiSi₂) is employed as a metal silicide film, some degree of residual native oxide film can be disregarded since the native oxide film can be reduced by Ti. In the case of Co however, it is considered that since Co is relatively poor in reducing power as compared with that of Ti, the silicidation reaction thereof is obstructed due to the residual native oxide film, thus resulting in the generation of defective formation of Co silicide.

The reasons for causing a thick native oxide film to generate in the vicinity of the boundary can be explained as follows. Namely, due to a misalignment of a resist mask on the occasion of performing an ion implantation, ions of opposite impurity types may be allowed to enter into a region where only an N-type impurity ion (As ion or P ion) or only a P-type impurity ion (B ion) should be implanted. In that case, in the region where not only P-type but also N-type impurity ions are implanted, the density of impurities is caused to increase. There are experimental results which indicated that on a polysilicon surface where the impurity density was relatively high, the growth rate of native oxide film became higher. Therefore, it is assumed that in a region where not only P-type but also N-type impurity ions are implanted, the growth of native oxide film is accelerated as compared with other regions.

The thickness of the aforementioned thick native oxide film is within the range of about 2 to 5 nm. As for the width of defective region of Co silicide, it varies depending on the alignment accuracy of resist, on the condition of apparatus and on the thickness of the native oxide film, but may be within the range of about 0.1 to 0.2 μm.

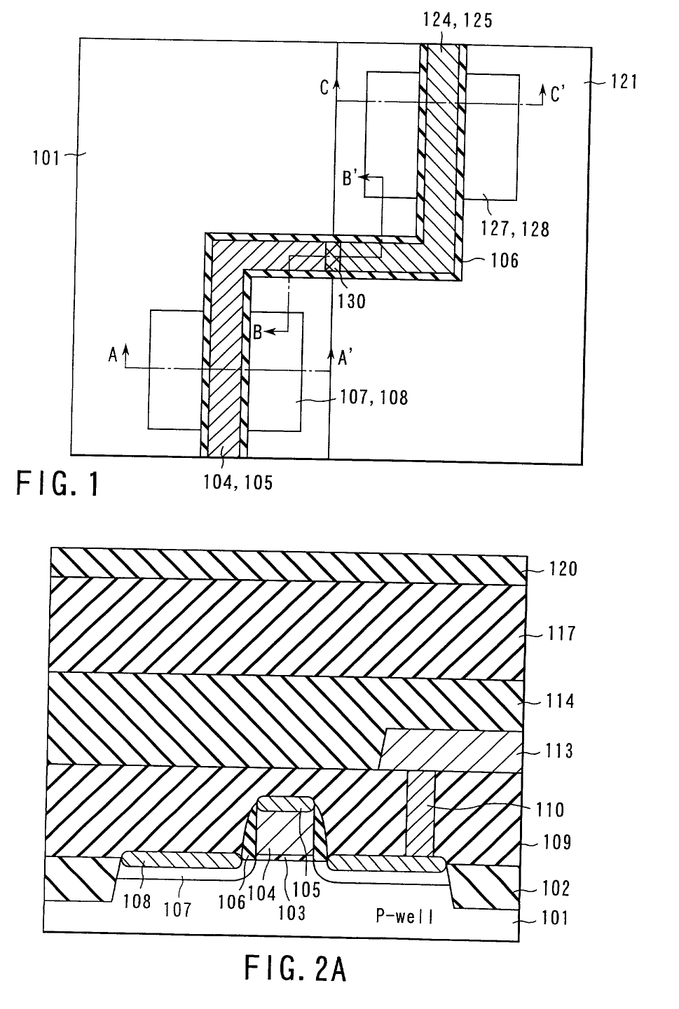

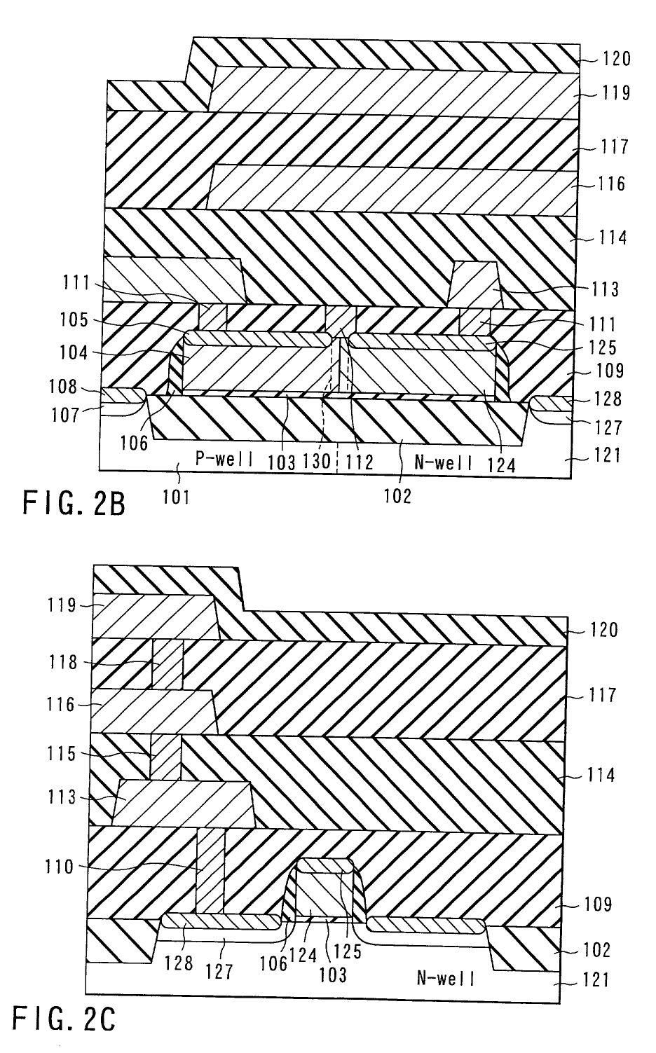

FIG. 1 is a plan view illustrating a part of the structure of a semiconductor device according to one embodiment of the present invention. FIG. 2A is a cross-sectional view taken along the line A-A′ of FIG. 1. FIG. 2B is a cross-sectional view taken along the line B-B′ of FIG. 1. FIG. 2C is a cross-sectional view taken along the line C-C′ of FIG. 1.

In a surface region of a silicon substrate, there are formed a P-type well 101, an N-type well 121 and an isolation insulating film 102. Over the P-type well 101 as well as over the N-type well 121, there are formed an N-type polysilicon wiring 104 and a P-type polysilicon wiring 124 with a gate insulating film 103 being interposed therebetween. A sidewall insulating film 106 is formed on the sidewall of the N-type polysilicon wiring 104 as well as on the sidewall of the P-type polysilicon wiring 124. In the N-type MIS transistor region, an N-type source/drain 107 is formed in the surface region of the P-type well 101 with the polysilicon wiring 104 being interposed between the N-type source/drain 107. In the P-type MIS transistor region, a P-type source/drain 127 is formed in the surface region of the N-type well 121 with the polysilicon wiring 124 being interposed between the P-type source/drain 127.

On the surfaces of the N-type source/drain 107 and the P-type source/drain 127, there are formed Co silicide electrodes 108 and 128, respectively. On the surfaces of the polysilicon wirings 104 and 124, there are formed Co silicide wirings 105 and 125, respectively. By way of the laminate structure of the polysilicon wiring 104 and the Co silicide wiring 105, a gate wiring including the gate electrode of N-type MIS transistor is formed. On the other hand, by way of the laminate structure of the polysilicon wiring 124 and the Co silicide wiring 125, a gate wiring including the gate electrode of P-type MIS transistor is formed.

Gate wirings are covered with an interlayer insulating film 109 having a flattened surface. This interlayer insulating film 109 is provided with a plurality of holes, in each of which a metal electrode (conductive connection member) is buried. An electrode 112 is formed on the boundary region 130 of the N-type polysilicon wiring 104 and the P-type polysilicon wiring 124. This electrode 112 has a portion corresponding to the boundary region 130 of the N-type polysilicon wiring 104 and the P-type polysilicon wiring 124 and is connected with the silicide wiring 105 and the silicide wiring 125. These silicide wirings 105 and 125 are also connected with corresponding electrodes 111. Further, the silicide electrodes 108 and 128 are connected with corresponding electrodes (contact plugs) 110.

Wirings 113 are formed on the interlayer insulating film 109 and connected with corresponding electrodes 110 and 111. Each wiring 113 is covered with an interlayer insulating film 114 having a flattened surface. This interlayer insulating film 114 is provided with a via-hole, in which a W via-electrode 115 is buried in contact with the wiring 113.

A wiring 116 which is connected with the W via-electrode 115 is formed on the interlayer insulating film 114. This wiring 116 is covered with an interlayer insulating film 117 having a flattened surface. This interlayer insulating film 117 is provided with a via-hole, in which a W via-electrode 118 is buried in contact with the wiring 116. A wiring 119 which is connected with the W via-electrode 118 is formed on the interlayer insulating film 117. The surfaces of the interlayer insulating film 117 and the wiring 119 are covered with a passivation film 120.

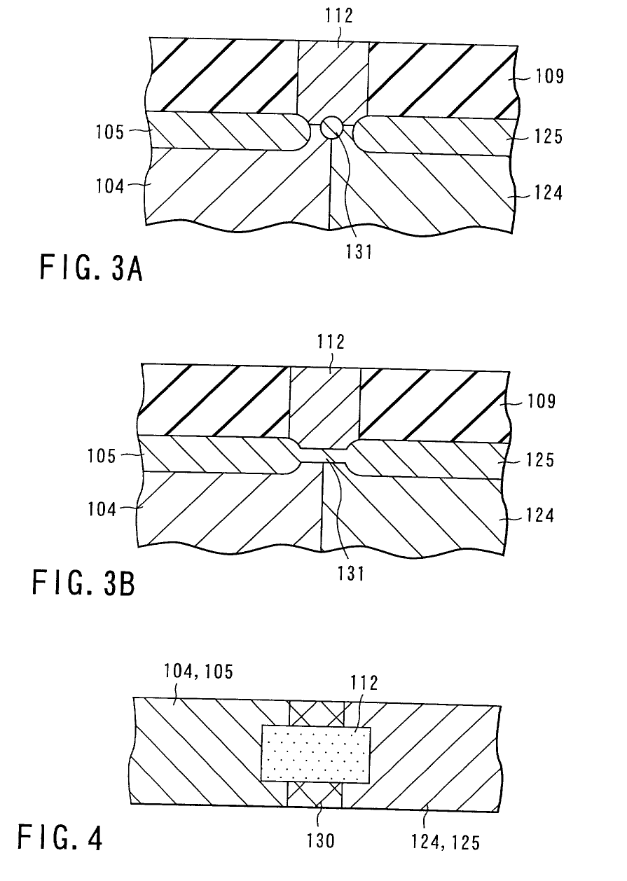

In the semiconductor device described above, a defective region of silicide exists on the boundary region 130 of the N-type polysilicon wiring 104 and the P-type polysilicon wiring 124. The defective region in this case includes various states, e.g. a state where no silicide film is grown, a state where a silicide film 131 is partially formed as shown in FIG. 3A, or a state where a silicide film 131 is formed thinner than the silicide wirings 105 and 125 as shown in FIG. 3B. The formation of these defective regions can be attributed, as already explained above, to the existence of a region where not only an N-type impurity but also a P-type impurity are contained in the boundary region 130 of the N-type polysilicon wiring 104 and the P-type polysilicon wiring 124.

In this embodiment, as schematically shown in FIG. 4 for instance, the electrode 112 is formed so as to cover at least part of the boundary region 130, and the silicide wiring 105 is connected with the silicide wiring 125 by this electrode 112. Therefore, even if silicide is not formed between the silicide wirings 105 and 125, it is possible to secure an electric connection between the silicide wirings 105 and 125.

By the way, depending on the direction of the misalignment of the resist mask, both of N-type impurity and P-type impurity are not permitted to be introduced into the boundary region 130, or only one of N-type impurity and P-type impurity is permitted to be introduced into the boundary region 130. In such a case, a silicide film which is contiguous to the silicide wiring 105 as well as to the silicide wiring 125 may be normally formed on the boundary region 130.

However, since the possibility of generating a defective region of silicide is much influenced depending on factors involved on the occasion of manufacturing a semiconductor device, it is impossible to predict such a possibility before the manufacturing. In this embodiment, the maximum width of a region (the width in the direction of wiring) within which a defective region may be generated is estimated in advance, and on the basis of the estimated value, the pattern of the electrode 112 is designed in advance such that the width of the designed pattern (for example, not less than 0.2 μm) is larger than the estimated maximum width (for example, about 0.1-0.2 μm). Due to this countermeasure, it is now possible, irrespective of whether or not defective region of silicide is permitted to generate, to reliably obtain a wiring having inherent characteristics of Co silicide of low electric resistance, thereby making it possible to improve the yield of wiring.

Further, in this embodiment, a silicide wiring is not partitioned by way of patterning as done in the prior art. Therefore, it is possible to minimize an increase of area that may accompanied with the formation of the electrode 112, and at the same time, an increase of manufacturing steps due to the patterning process can be prevented. Further, the mutual diffusion of P-type impurities and N-type impurities may be suppressed at the defective region of silicide as in the case where a silicide wiring is partitioned by way of patterning.

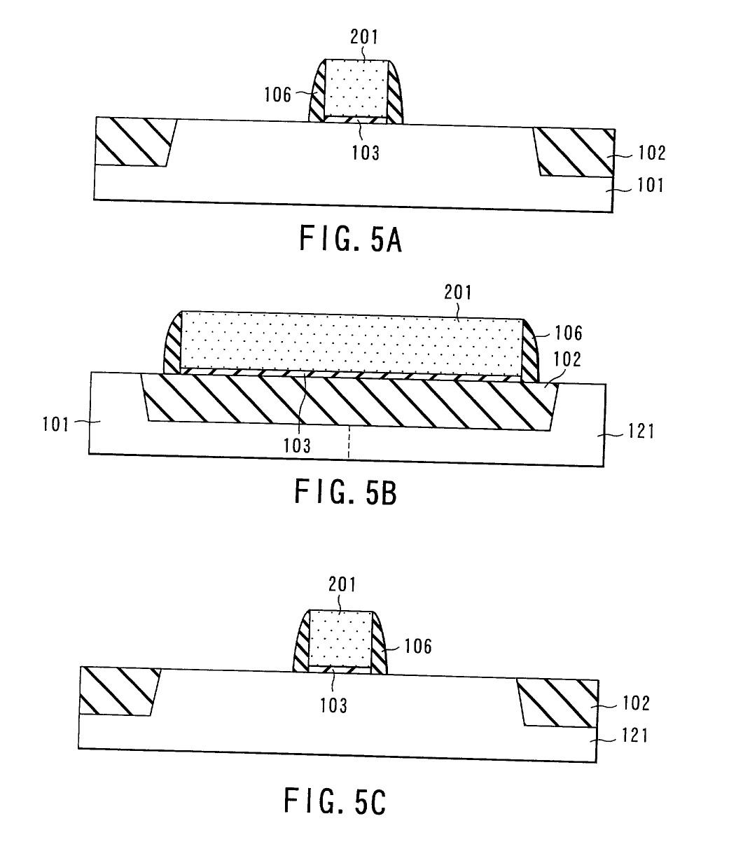

Next, the method of manufacturing a semiconductor device according to this embodiment will be explained with reference to FIGS. 5A, 5B, 5C through FIGS. 13A, 13B and 13C. FIGS. 5A through 13A are cross-sectional views each taken along the line A-A′ of FIG. 1; FIGS. 5B through 13B are cross-sectional views each taken along the line B-B′ of FIG. 1; and FIGS. 5C through 13C are cross-sectional views each taken along the line C-C′ of FIG. 1.

First of all, as shown in FIGS. 5A, 5B and 5C, by means of STI technique, an isolation insulating film 102 is formed in a surface region of a semiconductor substrate including a P-well 101 and an N-well 121. Then, a gate insulating film 103 is formed on the surfaces of the P-well 101 and the N-well 121, and a polysilicon film 201 is deposited on the gate insulating film 103. Then, a laminate layer of the gate insulating film 103 and the polysilicon film 201 is subjected to a patterning process so as to make it into a shape of gate wiring. Thereafter, a silicon nitride film is deposited all over the resultant surface, and the resultant silicon nitride film is etched by means of RIE to form a sidewall insulating film 106 on the sidewall of the laminate layer.

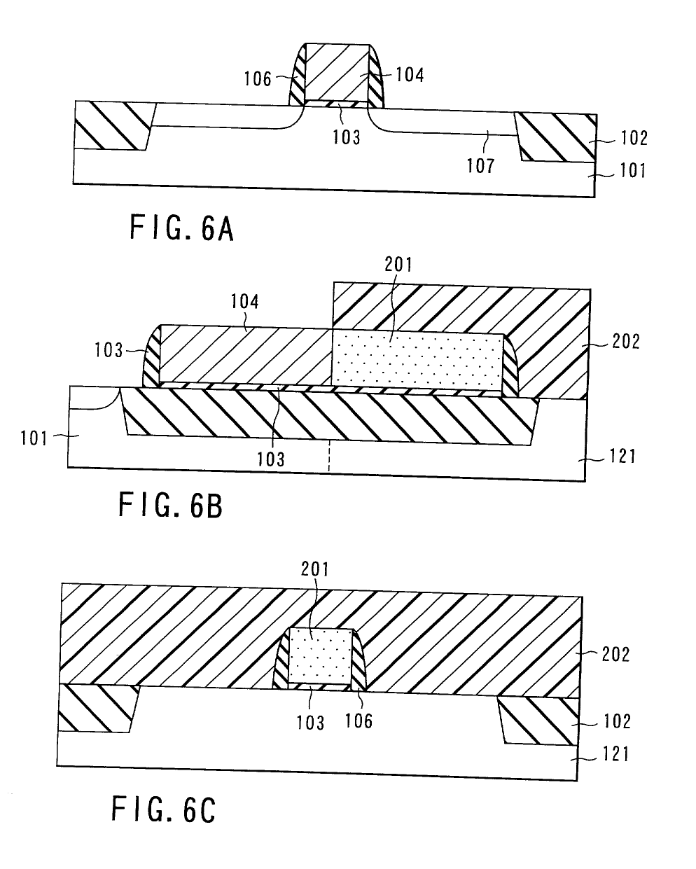

Then, as shown in FIGS. 6A, 6B and 6C, a resist film 202 is formed over the N-well 121. Subsequently, by making use of the resist film 202 as a mask, an N-type impurity (As or P) is ion-implanted into the P-well 101 and the polysilicon film 201. Further, the N-type impurity is activated to thereby form an N-type source/drain 107 at the surface region of the P-well 101, and at the same time, an N-type polysilicon wiring 104 is formed.

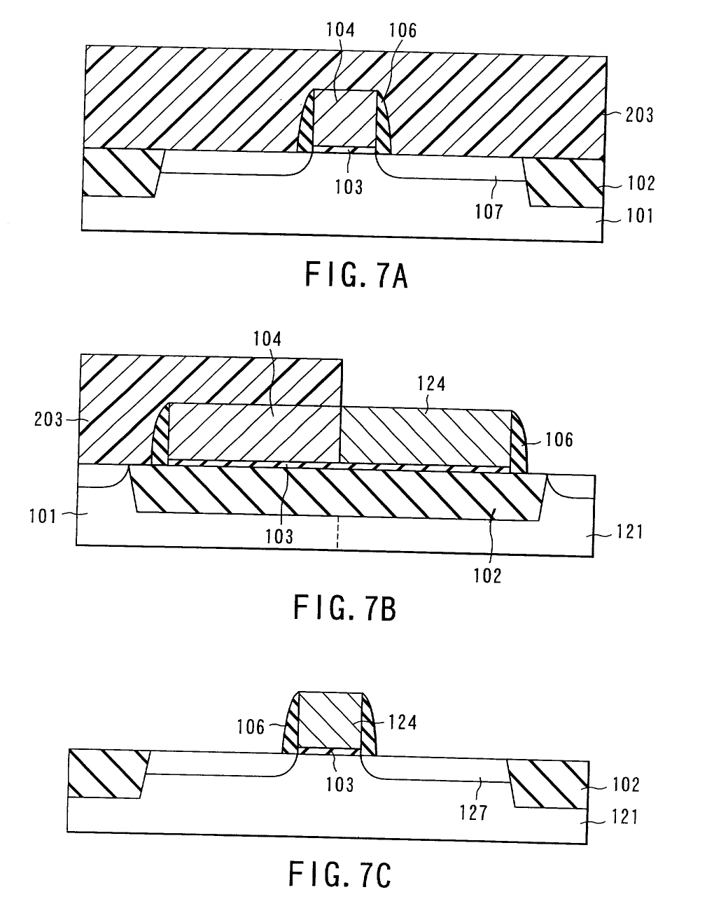

Then, as shown in FIGS. 7A, 7B and 7C, a resist film 202 is removed, and then, a resist film 203 is formed over the P-well 101. Thereafter, by making use of the resist film 203 as a mask, a P-type impurity (B) is ion-implanted into the N-well 121 and the polysilicon film 201. Further, the P-type impurity is activated to thereby form a P-type source/drain 127 at the surface region of the N-well 121, and at the same time, a P-type polysilicon wiring 124 is formed.

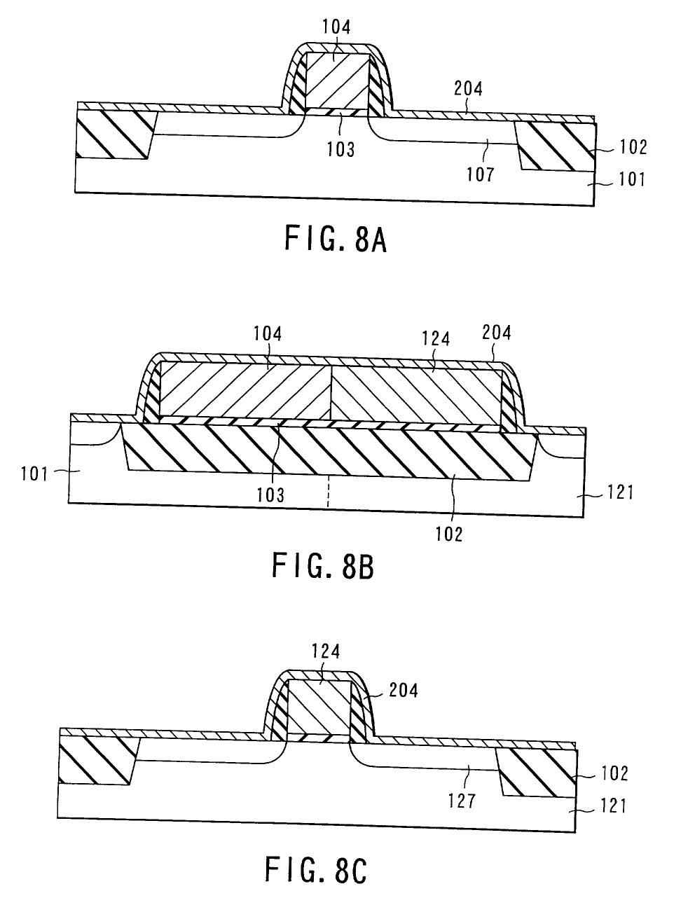

Then, as shown in FIGS. 8A, 8B and 8C, after a resist film 203 is removed, a native oxide film that has been formed on the surfaces of the source/drain 107 and 127 and on the surfaces of the polysilicon wirings 104 and 124 is removed by making use of a chemical liquid treatment, etc. Thereafter, a Co film 204 is deposited all over the resultant surface.

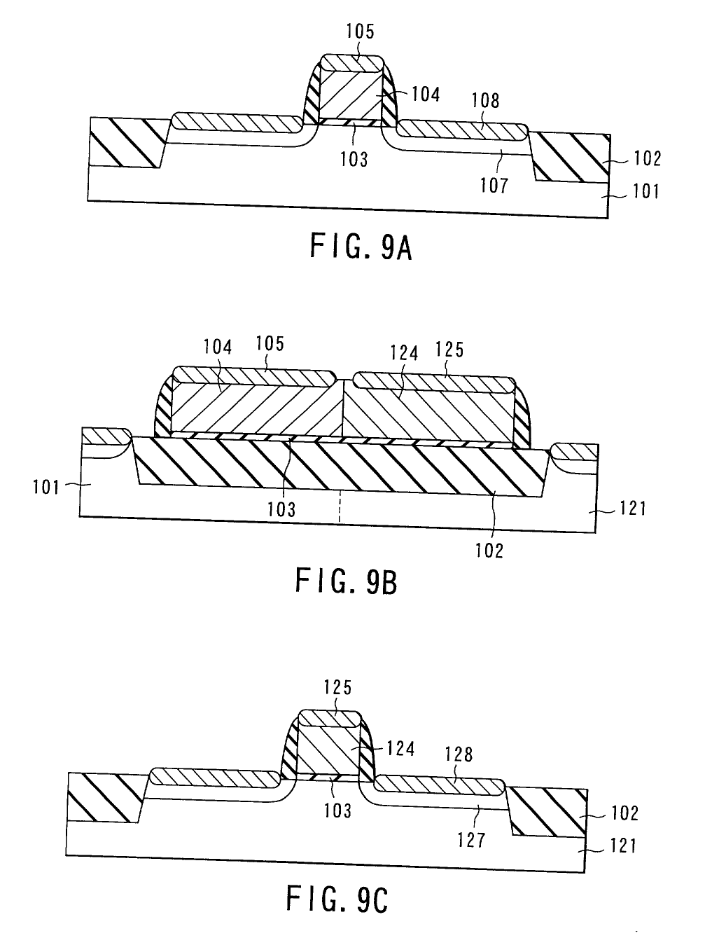

Then, as shown in FIGS. 9A, 9B and 9C, by way of heat treatment, the Co film 204 is allowed to react with silicon. As a result, a Co silicide film (CoSi₂ film) 105 is formed on the N-type polysilicon wiring 104, and at the same time, a Co silicide film 125 is formed on the P-type polysilicon wiring 124. Further, a Co silicide film 108 is formed on the source/drain 107, and a Co silicide film 128 is formed on the source/drain 127. Thereafter, unreacted portion of the Co film is removed. In this embodiment, both of N-type impurity and P-type impurity are permitted to enter into a boundary region of the N-type polysilicon wiring 104 and the P-type polysilicon wiring 124. Therefore, by the same reason as already explained above, a defective region of Co silicide film is permitted to exist on a boundary region of the N-type polysilicon wiring 104 and the P-type polysilicon wiring 124.

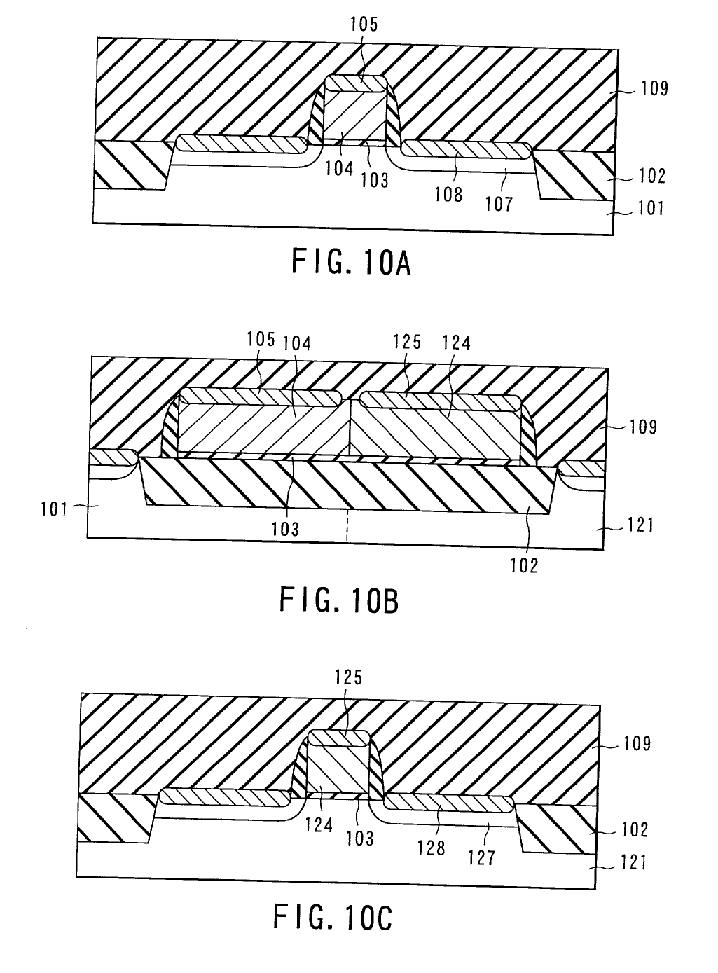

Then, as shown in FIGS. 10A, 10B and 10C, an interlayer insulating film 109 having a flattened surface is formed so as to cover the gate wiring having a laminate structure of a polysilicon film and a Co silicide film.

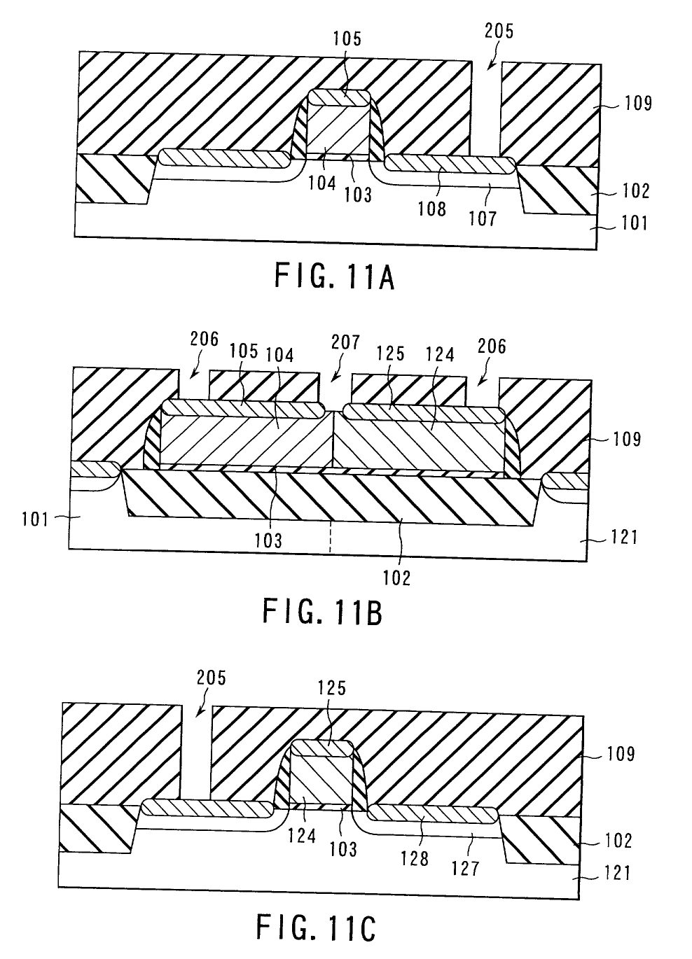

Then, as shown in FIGS. 11A, 11B and 11C, a plurality of holes are concurrently formed in the interlayer insulating film 109. Namely, a hole 207 is formed over a boundary region of the N-type polysilicon wiring 104 and the P-type polysilicon wiring 124; holes 206 are formed over the silicide wirings 105 and 125, respectively; and holes 205 are formed over the Co silicide electrodes 108 and 128, respectively.

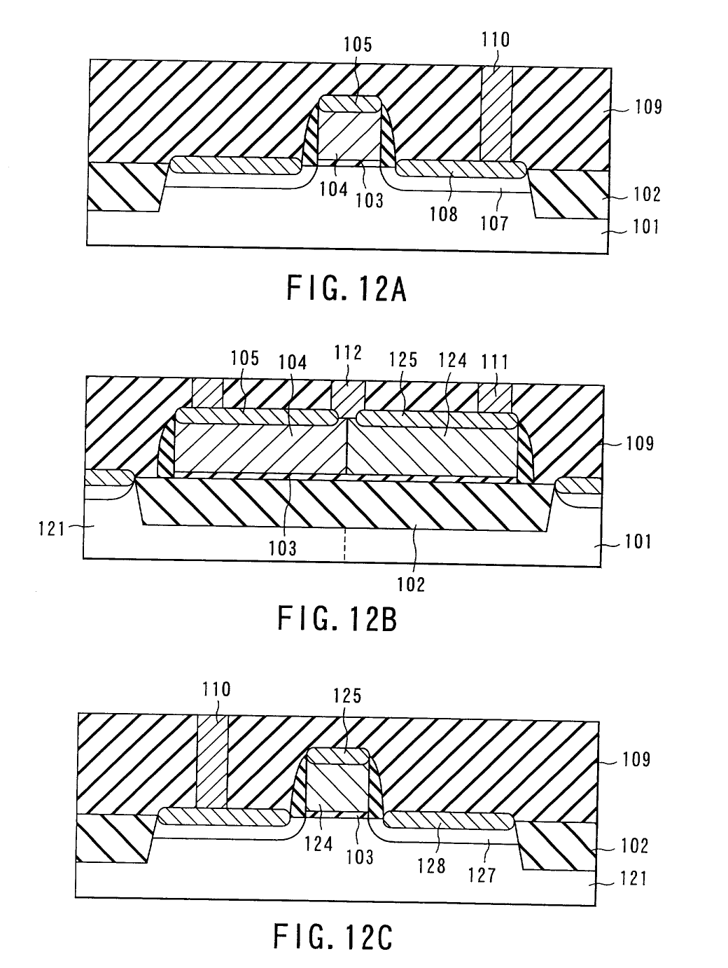

Then, as shown in FIGS. 12A, 12B and 12C, a metallic film of multi-layer structure composed of Ti, TiN and W layers is concurrently buried in these holes 205, 206 and 207. As a result, an electrode 112 is formed in the hole 207, thereby enabling the silicide wiring 105 to be connected with the silicide wiring 125 through this electrode 112. Additionally, an electrode 111 is formed in the hole 206, and an electrode 110 is formed in the hole 205.

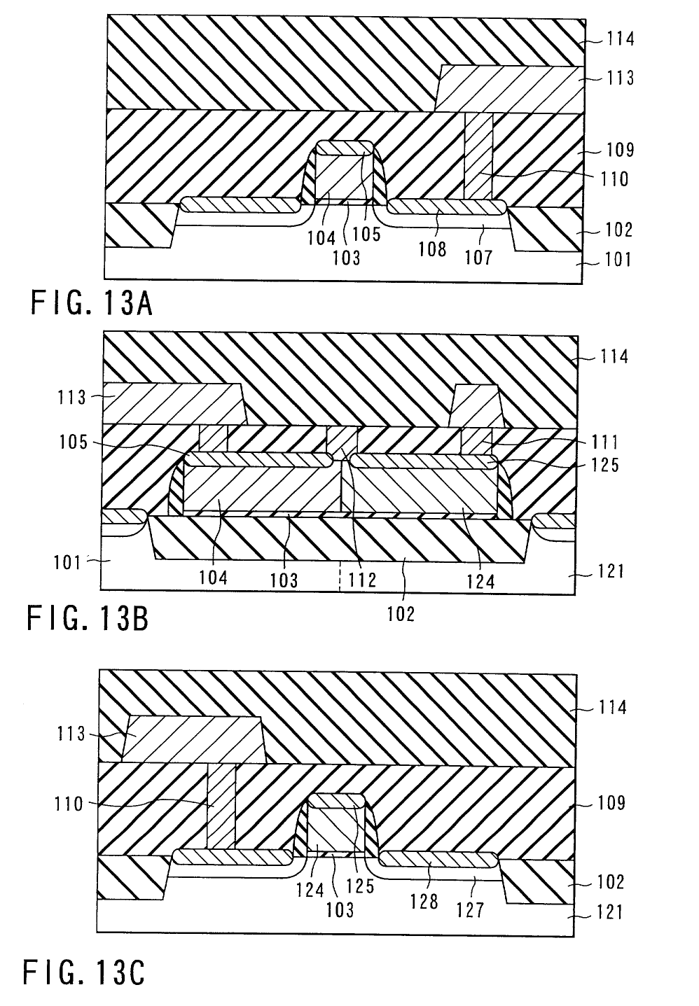

Then, as shown in FIGS. 13A, 13B and 13C, by means of a sputtering method, etc., a multi-layer wiring film having a Ti/TiN/AlCu/Ti/TiN multi-layer structure for instance is deposited on the surface of the interlayer insulating film 109. Further, this multi-layer wiring film is patterned to form a wiring 113. Thereafter, an interlayer insulating film 114 is formed on the interlayer insulating film 109 so as to cover the wiring 113.

Subsequently, a via-electrode 115, a wiring 116, an interlayer insulating film 117, a via-electrode 118, a wiring 119 and a passivation film 120 are formed to obtain a semiconductor device as shown in FIGS. 2A, 2B and 2C.

According to the aforementioned manufacturing method, since the electrode 112 is enabled to be formed simultaneous with the formation of electrodes 110 and 111, the electrode 112 can be formed on a boundary region of the N-type polysilicon wiring 104 and the P-type polysilicon wiring 124 without necessitating any special additional step.

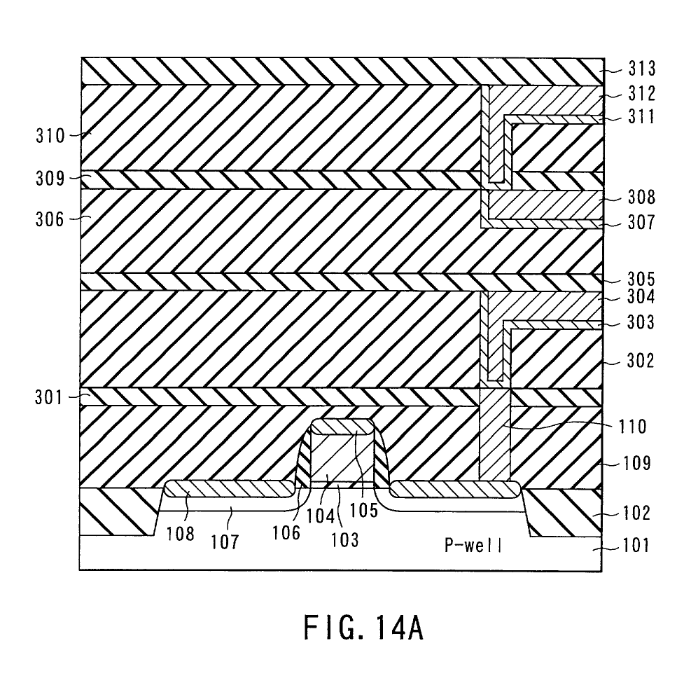

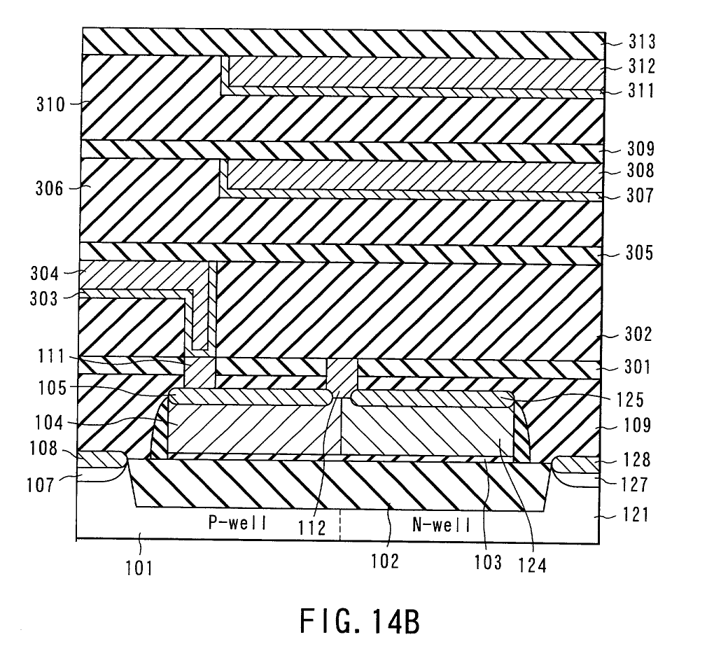

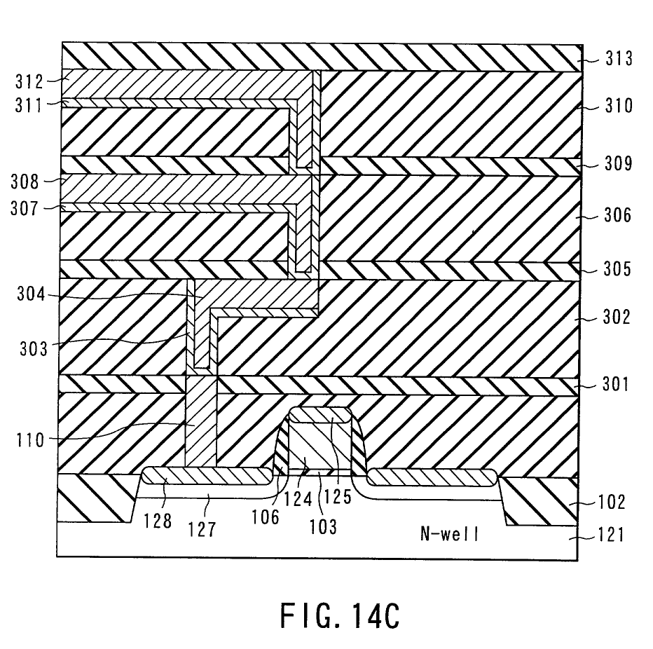

By the way, the structure over the interlayer insulating film 109 may be formed by means of a dual damascene process as shown in FIGS. 14A, 14B and 14C. In FIGS. 14A, 14B and 14C, the reference numbers 301, 305 and 309 represent a silicon nitride film; the reference numbers 302, 306 and 310 represent an interlayer insulating film; the reference numbers 303, 307 and 311 represent a barrier metal; the reference numbers 304, 308 and 312 represent a wiring and plug; and the reference number 313 represents a passivation film.

Although the foregoing embodiment has been explained taking a cobalt silicide film as an example, it is also possible to employ, instead of the cobalt silicide film, a nickel silicide (NiSi₂) film or a palladium silicide (PdSi₂) film. Further, it is also possible to employ a silicide film where two or more elements selected from cobalt, nickel and palladium are contained therein. Cobalt, nickel and palladium are inferior in reducing power as compared with titanium, so that the aforementioned defective region of silicide would be formed. Therefore, the application of the same method as the aforementioned embodiment would be also useful in the employment of these elements.

It is noted that, the semiconductor device to be obtained from the aforementioned embodiment can be applied to a Logic device, to an SRAM device, or to a DRAM/Logic-mixed device, each of which has a 0.18 μm or 0.15 μm wiring rule.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a first wiring formed above the semiconductor substrate and including a first polysilicon film containing a first conductivity type impurity and a first silicide film formed on the first polysilicon film and containing at least one of Co, Ni and Pd;
a second wiring formed above the semiconductor substrate and including a second polysilicon film containing a second conductivity type impurity and connected to the first polysilicon film and a second silicide film formed on the second polysilicon film and containing at least one of Co, Ni and Pd; and
a conductive connection member having a portion corresponding to a boundary region of the first polysilicon film and the second polysilicon film and connected to the first silicide film and the second silicide film.

2. The semiconductor device according to claim 1, wherein the first wiring includes a gate electrode of a first conductivity type MIS transistor, and the second wiring includes a gate electrode of a second conductivity type MIS transistor.

3. The semiconductor device according to claim 1, wherein the conductive connection member covers at least a part of the boundary region.

4. The semiconductor device according to claim 1, wherein the boundary region contains at least one of the first conductivity type impurity and the second conductivity type impurity.

5. The semiconductor device according to claim 1, wherein no silicide film is formed on the boundary region.

6. The semiconductor device according to claim 1, wherein a third silicide film is formed on at least a part of the boundary region.

7. The semiconductor device according to claim 6, wherein the third silicide film is thinner in thickness than the first and second silicide films.

8. The semiconductor device according to claim 1, further comprising an insulating film covering the first and second wirings, and wherein the conductive connection member is formed in the insulating film.

9. The semiconductor device according to claim 8, further comprising an additional conductive connection member formed in the insulating film and spaced apart from the conductive connection member, the additional conductive connection member being formed of the same material as that of the conductive connection member.

10. The semiconductor device according to claim 9, wherein an upper surface of the conductive connection member, an upper surface of the additional conductive connection member and an upper surface of the insulating film are positioned substantially within a common plane.

11. The semiconductor device according to claim 9, wherein the additional conductive connection member is connected to the first silicide film, the second silicide film or a silicide film formed on the semiconductor substrate.

12. The semiconductor device according to claim 9, further comprising an upper wiring formed on the insulating film and connected to the additional conductive connection member.

13. A method of manufacturing a semiconductor device comprising:
forming a polysilicon film above a semiconductor substrate;
introducing a first conductivity type impurity into a first region of the polysilicon film and introducing a second conductivity type impurity into a second region of the polysilicon film;
forming a metal film containing at least one of Co, Ni and Pd on the polysilicon film including the first and second regions;
causing the metal film to react with the polysilicon film to form a first silicide film in the first region and a second silicide film in the second region; and
forming a conductive connection member on a boundary region of the first region and the second region to connect the conductive connection member to the first silicide film and the second silicide film.

14. The method according to claim 13, wherein the conductive connection member covers at least a part of the boundary region.

15. The method according to claim 13, further comprising forming an insulating film covering the first and second silicide films, and wherein forming the conductive connection member includes forming the conductive connection member in the insulating film.

16. The method according to claim 15, wherein forming the conductive connection member includes forming an additional conductive connection member in the insulating film.

17. The method according to claim 16, wherein forming the additional conductive connection member includes connecting the additional conductive connection member to the first silicide film, the second silicide film or a silicide film formed on the semiconductor substrate.

18. The method according to claim 16, further comprising forming an upper wiring on the insulating film to connect the upper wiring to the additional conductive connection member.

19. The method according to claim 13, wherein introducing the first conductivity type impurity into the first region of the polysilicon film includes introducing the first conductivity type impurity into a second conductivity type region of the semiconductor substrate, and introducing the second conductivity type impurity into the second region of the polysilicon film includes introducing the second conductivity type impurity into a first conductivity type region of the semiconductor substrate.

20. The method according to claim 19, wherein forming the metal film on the polysilicon film includes forming the metal film on the semiconductor substrate including the first conductivity type region and the second conductivity type region, and causing the metal film to react with the polysilicon film includes causing the metal film to react with the semiconductor substrate to form a third silicide film in the first conductivity type region and a fourth silicide film in the second conductivity type region.
